(19) United States
(12) Patent Application Publication
(10) Pub. No.: US 2020/0321228 A1
(43) Pub. Date: Oct. 8, 2020

(54) METHOD OF MANUFACTURING A LEAD FRAME, METHOD OF MANUFACTURING AN ELECTRONIC APPARATUS, AND ELECTRONIC APPARATUS

(71) Applicant: SONY CORPORATION, TOKYO (JP)

(72) Inventors: KOYO HOSOKAWA, KANAGAWA (JP); HIROSHI OZAKI, KANAGAWA (JP)

(21) Appl. No.: 16/301,203

(22) PCT Filed: Apr. 26, 2017
(86) PCT No.: PCT/JP2017/016571

§ 371 Date: Nov. 13, 2018

(30) Foreign Application Priority Data
May 27, 2016 (JP) 2016-106002

(51) Int. Cl. H01L 21/67; H01L 23/00

(52) U.S. Cl. CPC H01L 21/67144; H01L 2224/48247; H01L 2224/32145; H01L 24/07

(57) ABSTRACT

[Object] Provided is a method of manufacturing a lead frame capable of forming connection terminals in a plurality of rows around a circuit chip without requiring a complex manufacturing process and many processes. [Solving Means] The method of manufacturing a lead frame includes attaching a tape member to a lead frame member including at least a lead frame rim. A lead frame part including at least one of a die pad or a connection terminal is mounted on the tape member in the lead frame rim.

### TECHNICAL FIELD

The present technology relates to a technology of a lead frame used in an electronic apparatus such as an electronic component or an electronic circuit.

### BACKGROUND ART

A lead frame used in a QFN (Quad flat non-leaded) type package (electronic apparatus) is disclosed in Patent Literature 1. The electronic apparatus includes a lead frame including a plurality of lead terminals and an island (die pad) made of a different material or having different thickness from the lead frame. In addition, before a process of sealing with resin, a tape member is attached to the bottom surface (rear surface) of the lead frame, and the lead frame and the island are fixed in a single body via the tape member (described in paragraphs [0036] and [0047] of the specification).

A technology of forming a lead frame including terminals by the photolithography and etching technology is disclosed in Patent Literature 2. For example, half-etching is performed as etching. As a result, the density of terminals may be increased. Specifically, terminals are formed in a plurality of rows in a diameter direction such that the terminals surround a semiconductor element arranged on the center (refer to paragraphs [0020] and [0022] of the specification).

### CITATION LIST

### Patent Literature

Patent Literature 1: Japanese Patent No. 4311294

Patent Literature 2: Japanese Patent Application Laid-open No. 2013-62549

### DISCLOSURE OF INVENTION

### Technical Problem

In the technology of the above-mentioned Patent Literature 1, lead terminals are arranged in one outer circular row. Thus, as the number of the lead terminals increases, the package size is increased. When the package size is increased, the reliability of mounting on a board of the electronic apparatus becomes lower.

In the technology of the above-mentioned Patent Literature 2, a complex manufacturing process of photolithography and etching is needed. In addition, the number of processes and cost increase.

It is an object of the present disclosure to provide a method of manufacturing a lead frame capable of forming connection terminals in a plurality of rows around a circuit chip without requiring a complex manufacturing process and many processes.

In addition, it is an object of the present disclosure to provide a thinner electronic apparatus using a lead frame.

### Solution to Problem

In order to attain the above-mentioned objects, a method of manufacturing a lead frame according to an embodiment includes attaching a tape member to a lead frame member including at least a lead frame rim.

A lead frame part including at least one of a die pad or a connection terminal is mounted on the tape member in the lead frame rim.

In other words, the process of attaching the tape member to the lead frame member is separated from the process of attaching the lead frame part to the tape member. Due to this, a connection terminal may be arranged in a plurality of rows without requiring a complex manufacturing process and many processes.

The method of manufacturing a lead frame may further include forming the lead frame part by at least die-cutting a metal plate before the step of mounting the lead frame part on the tape member.

The step of forming the lead frame part may include forming a recess part on the metal plate by stamping. The die-cutting may be performed after forming the recess part so that the lead frame part includes the recess part.

The lead frame part may have a specific shape such as the recess part, and a lead frame high-resistant to heat process may be realized.

The lead frame member may include the die pad and a first connection terminal group provided around the die pad. The step of mounting the lead frame part on the tape member may include mounting a second connection terminal group on the tape member so that the second connection terminal group is arranged between the die pad and the first connection terminal group.

As a result, the lead frame including the connection terminals in a plurality of rows is manufactured.

The lead frame member may include a first connection terminal group provided around the die pad.

The step of mounting the lead frame part on the tape member may include mounting the die pad on a first position of the tape member and mounting a second connection terminal group on a second position of the tape member, the second position being around the first position and inside the first connection terminal group.

A method of manufacturing an electronic apparatus according to an embodiment includes attaching a tape member to a lead frame member including at least a lead frame rim.

A lead frame part including a die pad and a connection terminal is mounted on the tape member in the lead frame rim.

A circuit chip is mounted on the die pad.

The circuit chip is connected to the connection terminal by a wire.

The circuit chip and the wire are sealed with resin.

The lead frame member may include the die pad, and a connection terminal group provided around the die pad. The method of manufacturing an electronic apparatus may further include mounting an electronic element component between the die pad and the connection terminal group.

The lead frame member may include a connection terminal group provided around the die pad. The method of manufacturing an electronic apparatus may further include mounting the die pad on a first position of the tape member and mounting an electronic element component on a second position of the tape member, the second position being around the first position and inside the first connection terminal group.

In the present technology, mounting an electronic element component on the second position of the connection terminal groups in a plurality of rows may allow a miniaturized electronic apparatus to be manufactured.

An electronic apparatus according to an embodiment includes a die pad, connection terminal groups, a circuit chip, wires, and resin.

The die pad includes a bottom surface.

The connection terminal groups respectively include bottom surfaces, the bottom surfaces being arranged on a plane same as a reference plane, the reference plane including the bottom surface of the die pad, the connection terminal groups being arranged in a plurality of rows around the die pad.

The circuit chip is provided on the die pad.

The wires connect the circuit chip to a plurality of predetermined connection terminals of the connection terminal groups respectively.

The resin includes a bottom surface arranged on the reference plane and seals the circuit chip and the wires.

Since the respective bottom surfaces of the elements are arranged on the same reference plane, an electronic apparatus including connection terminals in a plurality of rows may be made thinner.

The plurality of circuit chips may be provided in a layered state. A first circuit chip of the plurality of circuit chips and a connection terminal group in a first row of the connection terminal groups may be connected respectively by the wires. A second circuit chip of the plurality of circuit chips and a connection terminal group in a second row of the connection terminal groups may be connected respectively by the wires, height of the connection terminal group in the second row being different from height of the connection terminals in the first row.

The respective components of the electronic apparatus are arranged in a dense state since the circuit chips have a layered state and the connection terminals have a plurality of rows, and miniaturization of the electronic apparatus may be realized.

### Advantageous Effects of Invention

As described above, according to the method of manufacturing of the present technology, it is possible to form connection terminals in a plurality of rows around a circuit chip without requiring a complex manufacturing process and many processes.

According to an electronic apparatus of the present technology, the electronic apparatus including connection terminals arranged in a plurality of rows around a die pad can be made thinner.

Note that the effects described above are not limitative, but any effect described in the present disclosure may be produced.

### BRIEF DESCRIPTION OF DRAWINGS

FIG. 1A is a plan view showing an electronic apparatus according to a first embodiment of the present technology. FIG. 1B is a cross-sectional view along A-A line of FIG. 1A.

FIGS. 2A to 2G are diagrams showing a method of manufacturing an electronic apparatus including a method of manufacturing a lead frame according to an embodiment of the present technology.

FIGS. 3A and 3B are plan views showing a lead frame member.

FIGS. 4A and 4B are diagrams showing an example 1 of manufacturing connection terminals as a lead frame part.

FIGS. 5A to 5C are diagrams showing an example 2 of manufacturing connection terminals as a lead frame part.

FIG. 6A is a plan view showing an electronic apparatus according to a second embodiment of the present technology. FIG. 6B is a cross-sectional view along B-B line of FIG. 6A.

FIG. 7A is a plan view showing an electronic apparatus according to a third embodiment of the present technology. FIG. 7B is a cross-sectional view along C-C line of FIG. 7A and shows the electronic apparatus mounted on a mount board.

FIG. 8A is a plan view showing an electronic apparatus according to a fourth embodiment of the present technology. FIG. 8B is a cross-sectional view along D-D line of FIG. 8A and shows the electronic apparatus mounted on a mount board.

FIG. 9 FIGS. 9A to 9F are diagrams showing electronic element components.

FIG. 10 is a cross-sectional view showing an electronic apparatus according to a fifth embodiment of the present technology.

### MODE(S) FOR CARRYING OUT THE INVENTION

Hereinafter, embodiments according to the present technology will be described with reference to the drawings.

### 1. First Embodiment

1. 1) Configuration of Electronic Apparatus

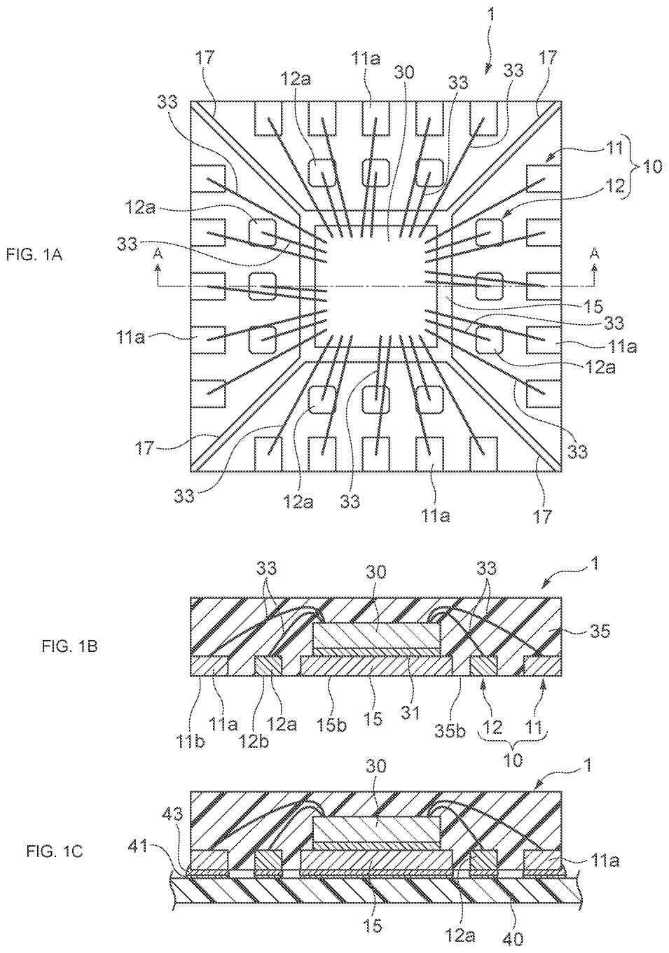

FIG. 1A is a plan view showing an electronic apparatus according to a first embodiment of the present technology. FIG. 1B is a cross-sectional view along A-A line of FIG. 1A.

The electronic apparatus 1 is a QFN (Quad flat non-leaded) packaged apparatus, which is a single-sided mold type package manufactured by using a lead frame described below.

The electronic apparatus 1 has a die pad (also called island) 15, a connection terminal group 10 arranged around the die pad 15 in a plurality of rows, and hanging parts 17. As described below, the die pad 15, the connection terminal group 10, and the hanging parts 17 are structured as a part of a lead frame member 20 in a process of manufacturing the electronic apparatus 1.

The connection terminal group 10 includes, for example, an outer-circular-row connection terminal group 11 (first connection terminal group), and an inner-circular-row connection terminal group 12 (second connection terminal group) provided between the outer peripheral rows and the die pad 15. The outer-circular-row connection terminal group 11 includes a plurality of connection terminals 11a. The inner-circular-row connection terminal group 12 includes a plurality of connection terminals 12a.

In addition, the electronic apparatus 1 includes a circuit chip 30 mounted via die bond 31 on the die pad 15 and wires (bonding wires) 33 connecting the circuit chip 30 to a plurality of predetermined connection terminals of the connection terminal group 10 respectively. In the present embodiment, all of the connection terminals 11a and the connection terminals 12a are connected to the circuit chip 30 by the wires 33. At least one of the connection terminals 11a or the connection terminals 12a may not be connected to the circuit chip 30.

Copper, copper alloy, 42Alloy, or the like is used as a material of the lead frame member 20 including the die pad 15, the connection terminals 11a, and the connection terminals 12a. Gold, copper, silver, or the like is used as a material of the wires 33.

The circuit chip 30 and the wires 33 are sealed by sealing resin 35. Note that the sealing resin 35 is not shown in FIG. 1A. For example, epoxy resin is used as the sealing resin 35. The die pad 15, the connection terminals 11a, and the connection terminals 12a are sealed by the sealing resin 35 so that at least a bottom surface 15b and bottom surfaces 11b and 12b (see FIG. 1B) are exposed from bottom surfaces 35b of the sealing resin 35. Note that the outer-circular-row connection terminal group 11 is sealed so that the outer sides are also exposed.

Here, in the method of manufacturing a semiconductor apparatus described in Patent Literature 2, not only the upper surface side of the lead frame but also the under surface (bottom surface) side are half-etched as mentioned above. The upper side of the lead frame is sealed with resin, but the bottom surface side is exposed from sealing resin so that a conductor is protruded.

On the other hand, in the present embodiment, the bottom surface 15b of the die pad 15, the bottom surfaces 11b and 12b of the connection terminal group 10, and the bottom surfaces 35b of the sealing resin 35 are arranged on the same plane (reference plane) substantially. Thus, the whole thickness of the electronic apparatus may be made smaller than that of the semiconductor apparatus of Patent Literature 2. In other words, the electronic apparatus 1 including the connection terminal group 10 arranged in a plurality of rows around the die pad 15 may be made thinner.

FIG. 1C shows the electronic apparatus 1 mounted on a mount board 40. The connection terminals 11a, the connection terminals 12a, and the die pad 15 of the electronic apparatus 1 are connected by solder 43 to pad electrodes 41 provided on the mount board 40. Note that, mostly, the die pad 15 is connected on the mount board 40 for grounding, and the die pad 15 may not necessarily be connected on to the mount board 40. That is, the die pad 15 may be in an open state.

1. 2) Method of Manufacturing Electronic Apparatus

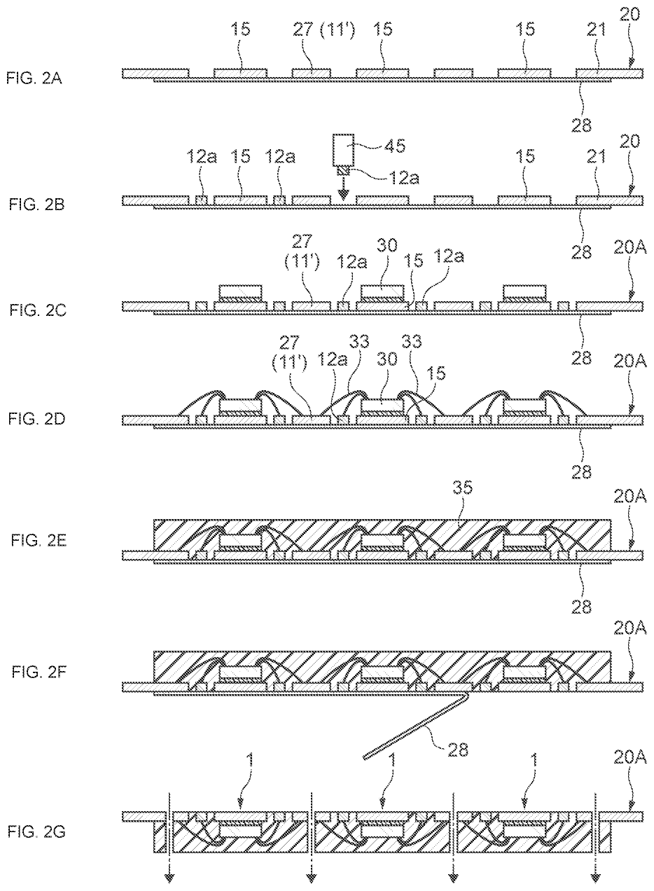

FIGS. 2A to 2G are diagrams showing a method of manufacturing the electronic apparatus 1 including a method of manufacturing a lead frame according to an embodiment of the present technology.

As shown in FIG. 2A, a tape member (lead frame tape) 28 is attached to the bottom surface of the lead frame member 20 having at least a lead frame rim 21. For example, the tape member 28 has an adhesive layer on the surface, and the adhesive layer is attached on the lead frame member 20. As a main material of the tape member 28, for example, a polyimide-series material is used.

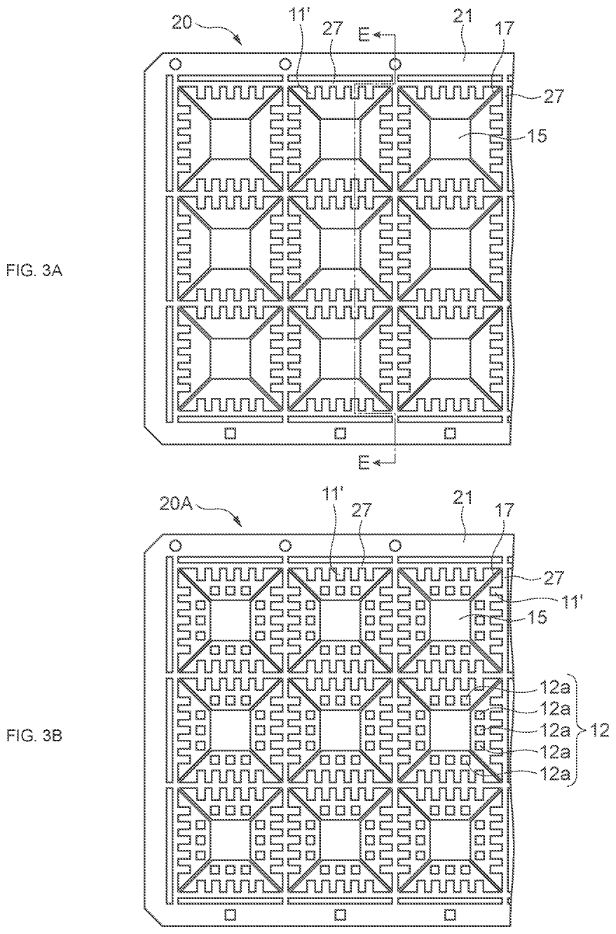

FIG. 3A is a plan view showing the lead frame member 20. FIG. 2A is a cross-sectional view along E-E line of FIG. 3A. In the process shown in FIG. 2A, the lead frame member 20 has the lead frame rim 21, tie bars 27 having regions 11′, which are formed as the outer-circular-row connection terminal group 11 later, the die pad 15, and the hanging parts 17. The tie bars 27 are provided in, for example, a matrix shape in the lead frame rim 21. The die pads 15 are respectively provided in the centers of the regions surrounded by rectangles in the tie bars 27. The outer-circular-row connection terminal group 11 is provided around the die pad 15 along the tie bars 27.

As shown in FIG. 2B, an absorption nozzle 45 of a parts-mounting machine, for example, absorbs the connection terminals 12a prepared as a lead frame part beforehand in another process as described below. The absorption nozzle 45 picks up and puts the connection terminals 12a between the die pad 15 and the outer-circular-row connection terminal group 11 (regions 11′). After that, the absorption nozzle 45 attaches and mounts the connection terminals 12a on the tape member 28. By repeating this process a plurality of times, the absorption nozzle 45 mounts the connection terminals 12a on the tape member 28. Thus, the inner-circular-row connection terminal group 12 is formed.

Chip-mounting machines, which mount and tile minimum IC chips or parts of several hundreds of μm such as WL-CSP (Wafer level Chip Size Package) rapidly on substrates with accuracy down to units of several μm, and manufacture pseudo wafers, have appeared in recent years. The machines are manufactured by JUKI Corporation (the former Sony Corporation), Yamaha Motor Co., Ltd., or the like. For example, a mount machine having a rotary head (mount head including a plurality of absorption nozzles arranged in circular shape) can mount the inner-circular-row connection terminal group 12 on the tape member 28 rapidly.

FIG. 3B is a plan view showing the lead frame 20A manufactured as described above. The inner-circular-row connection terminal group 12 mounted in another process (FIG. 2B) are provided around the die pad 15 being a center.

In the process of FIG. 2C and the subsequent processes, an electronic apparatus using the lead frame 20A is manufactured. As shown in FIG. 2C, the circuit chips (IC chips) 30 are mounted on the die pad 15 by the die bond 31 including conducive paste (die bonding process).

As shown in FIG. 2D, the circuit chips 30 are connected to the connection terminals 11a (regions 11′) and the connection terminals 12a respectively by the wires 33 (wire bonding process).

As shown in FIG. 2E, resin-sealing is performed. As a result, the sealing resin 35 seals at least the circuit chips 30 and the wires 33. The tape member 28 is attached to the bottom surface of the lead frame member 20. Thus, as described above, the bottom surface of the die pad 15, the bottom surfaces of the connection terminal group 10, and the bottom surface of the sealing resin 35 are arranged on the same plane (reference plane) substantially.

As shown in FIG. 2F, the tape member 28 is peeled from the lead frame 20A.

As shown in FIG. 2G, the lead frame 20A is cut into pieces (dicing process). Thus, the plurality of electronic apparatuses 1 are manufactured.

As described above, in the present embodiment, the process of attaching the tape member 28 to the lead frame member 20 is separated from the process of attaching the lead frame part to the tape member 28. Thus, the manufacturing method according to the present embodiment does not require complex and costly manufacturing processes such as photolithography or half-etching of Patent Literature 2. Besides, the inner-circular-row connection terminal group 12 and the outer-circular-row connection terminal group 11 can be formed in fewer processes. That is, the connection terminal group 10 can be arranged in a plurality of rows. Thus, cost reduction may be attained.

In addition, a mounting machine can mount connection terminals, and the degree of freedom to which the connection terminals are arranged improves. Thus, the inner-circular-row connection terminal group 12 may not be arranged in a straight line but, for example, staggered (for example, in a zigzag line).

1. 3) Method of Manufacturing Lead Frame Part

1. 3. 1) Method of Manufacturing Example 1

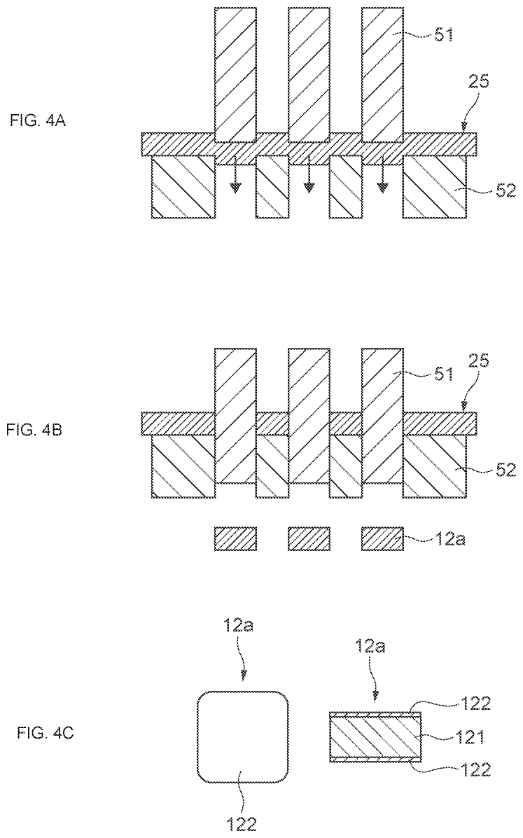

FIGS. 4A and 4B are diagrams showing an example 1 of manufacturing the connection terminals 12a as the lead frame part. A metal plate 25 being a material of the lead frame member 20 is prepared. The material of the metal plate 25 is, for example, copper, copper alloy, 42Alloy, or the like as described above. As shown in FIGS. 4A and 4B, the plurality of connection terminals 12a are formed from one metal plate 25 by die-cutting with a metal mold punch 51 and a corresponding metal mold die 52.

FIG. 4C shows the connection terminal 12a formed in this way. The left diagram of FIG. 4C is a plan view, and the right diagram of FIG. 4C is a cross-sectional view thereof. The structure of the connection terminal 12a allows the connection terminal 12a to be used regardless of the back and front sides. Before the die-cutting, the metal plate 25 is plated in advance. Thus, the connection terminal 12a having plated films 122 on surfaces of a body 121 is formed. The materials of the plated films 122 are, for example, Ni/Pd or Ni/Pd/Au. The plated films 122 make it easier and better to perform the processes of the wire bonding and soldering when the connection terminals 12a are mounted on the mount board 40.

Thus, according to the present embodiment, more lead frame parts may be manufactured by die-cutting more cheaply than the manufacturing method of Patent Literature 2 in which a lead frame is manufactured by half-etching.

1. 3. 2) Method of Manufacturing Example 2

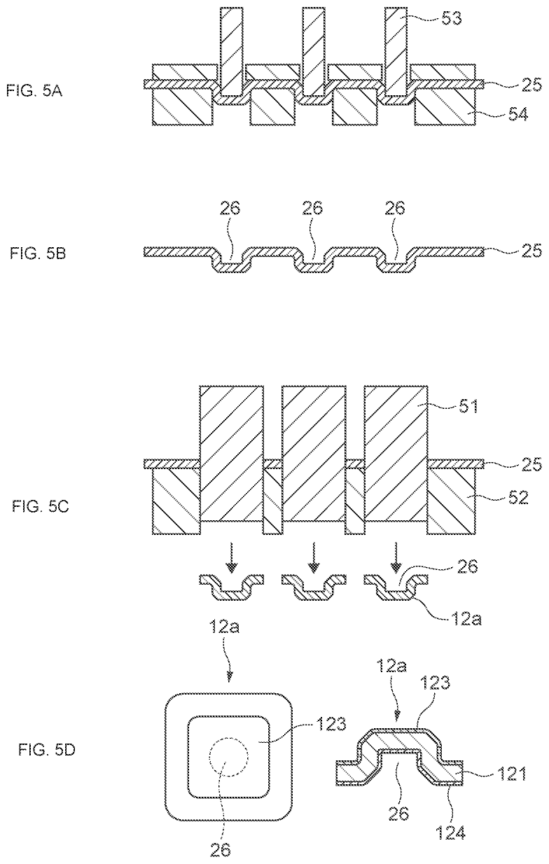

FIGS. 5A to 5C are diagrams showing an example 2 of manufacturing the connection terminals 12a as the lead frame part. A plurality of recess parts are formed on the metal plate 25 by stamping with a metal mold punch 53 and a metal mold die 54. In FIG. 5B, the metal plate 25 on which the recess parts 26 are formed is shown.

After forming the recess parts 26, the plurality of connection terminals 12a having the recess parts 26 are formed by the die-cutting with the metal mold punch 51 and the metal mold die 52.

FIG. 5D shows the connection terminal 12a formed in this way. The left diagram of FIG. 5D is a plan view, and the right diagram of FIG. 5D is a cross-sectional view thereof. Plated films 123 and 124 are respectively formed on the both surfaces of the body 121 for connecting to the wire 33 and the mount board 40. Specifically, the plated film 124 is formed on the inside of the recess part 26 to connect to the mount board 40, and the plated film 123 is formed on the opposite side to connect to the wire 33. The plated film 124 which connects to the mount board 40 is composed of, for example, Sn or the like. The plated film 123 which connects to the wire 33 is composed of, for example, Ag or the like.

The connection terminal 12a has the recess part 26, and solder enters into the recess part 26 when the connection terminal 12a is mounted by soldering. This alleviates stress by heat cycle or the like in the manufacturing processes and improves mounting certainty and reliability. Specifically, when surface to be soldered is flat, crack could be formed on the connecting solder due to the stress by the heat cycle. However, the recess part 26 may reduce the possibility of cracking. In addition, a plating material cheaper than the plating material of the connection terminals 12a shown in FIG. 4C may be used.

In the above-mentioned manufacturing method examples 1 and 2, the structures and the manufacturing methods for the connection terminals 12a as the lead frame part are taken as an example. The structures and the manufacturing methods can be applied, as described below, to the die pad 15 and/or the connection terminals 11a of the outer-circular-row connection terminal group 11 as the lead frame part.

### 2. Second Embodiment

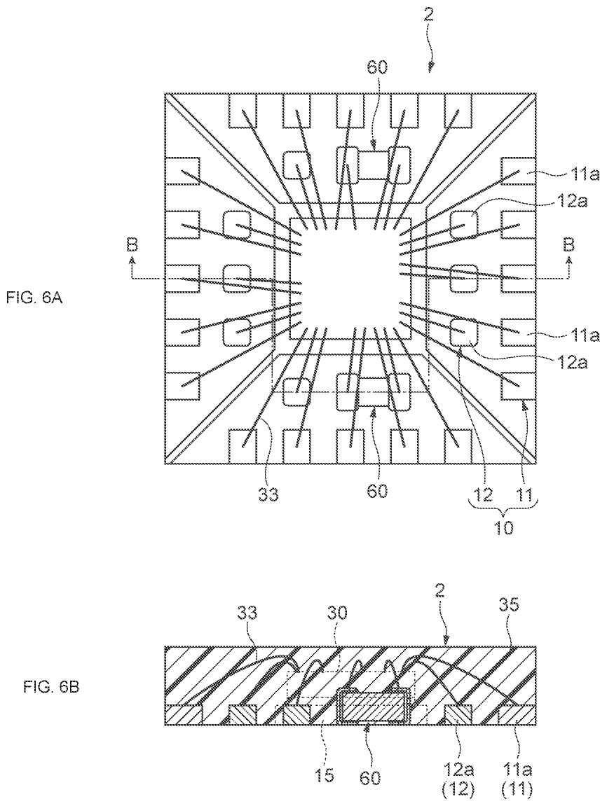

FIG. 6A is a plan view showing an electronic apparatus according to a second embodiment of the present technology. FIG. 6B is a cross-sectional view along B-B line of FIG. 6A. Hereinafter, the same reference symbols are attached to the substantially similar elements as the members, the functions, and the like of the electronic apparatus 1 according to the first embodiment shown in FIG. 1 and the like. Besides, the descriptions of those are omitted or simplified, and different points are mainly described.

The different point between an electronic apparatus 2 according to the second embodiment and that of the first embodiment is that some of the plurality of connection terminals 12a are replaced with an electronic element component, for example, a passive component 60. Typically, the passive component 60 is a laminated capacitor, but not limited. Resistance or other component may be used.

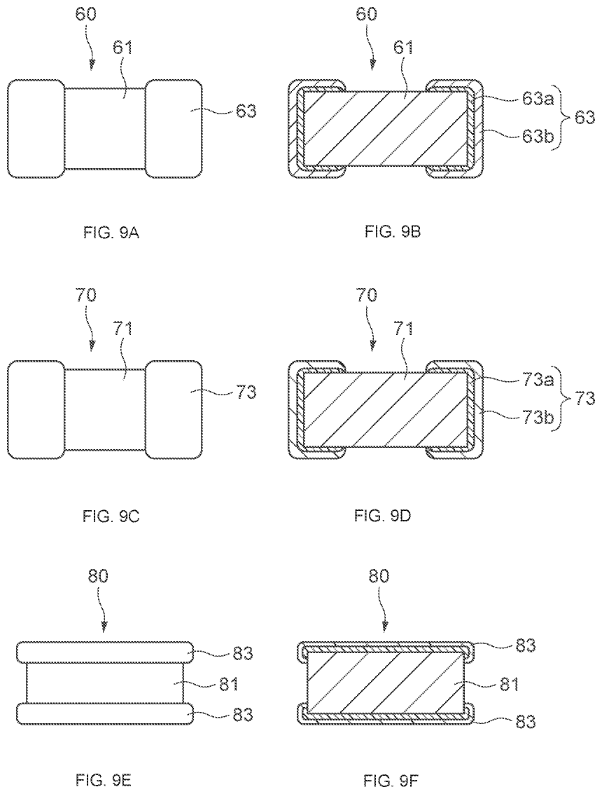

FIG. 9A is a side view showing the passive components 60 shown in FIGS. 6A and 6B, and FIG. 9B is a cross-sectional view thereof. The passive component 60 has a body 61 and electrode parts 63 provided on the both ends in a longitudinal direction of the body 61. Each electrode part 63 has a base electrode 63a and a plated film 63b formed on the base electrode 63a. The base electrode 63a is Cu, and the plated film 63b is Ag, for example. The plated film 63b made of Ag is suitable for the wire bonding between the circuit chip 30 and the electrode part 63.

### 3. Third Embodiment

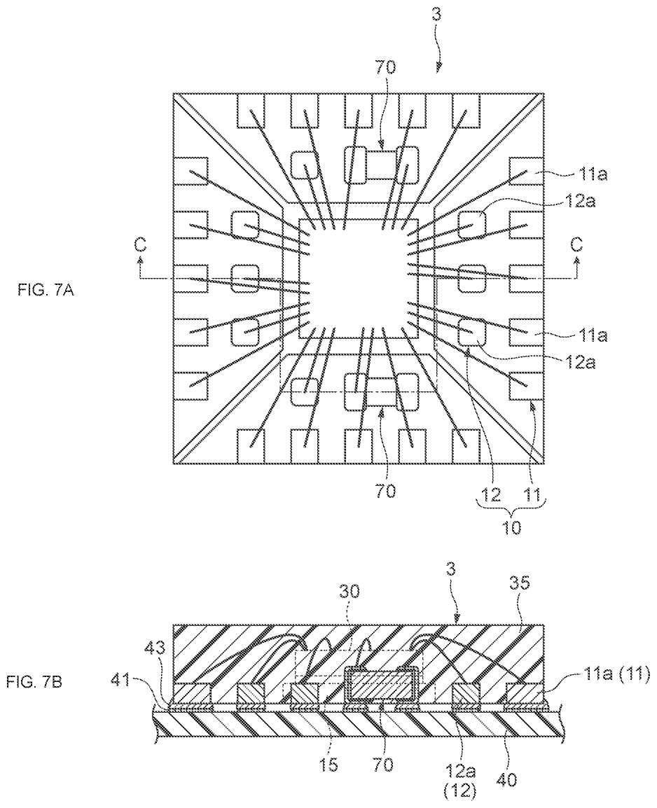

FIG. 7A is a plan view showing an electronic apparatus according to a third embodiment of the present technology. FIG. 7B is a cross-sectional view along C-C line of FIG. 7A and shows the electronic apparatus mounted on a mount board.

An electronic apparatus 3 according to the third embodiment has a passive component 70, of which structure is different from that of the electrode parts 63 of the passive components 60 of the second embodiment. The contents of FIGS. 7A and 6A are the same. FIG. 9C is a side view showing the passive component 70, and FIG. 9D is a cross-sectional view thereof.

Each electrode part 73 provided on the both ends of a body 71 of the passive component 70 has a base electrode 73a and a plated film 73b. The plated film 73b is a film formed by electroplating and is composed of Ni/Au, for example. The structure of the electrode part 73 is suitable for both the wire bonding and connecting to the pad electrodes 41 on the mount board 40 by solder.

Thus, the electronic element components such as the passive components 60, 70, or the like are arranged between the die pad 15 and the outer-circular-row connection terminal group 11. Due to this, complex processes are not needed, and the miniaturized electronic apparatuses 2 and 3 can be manufactured at low cost.

### 4. Fourth Embodiment

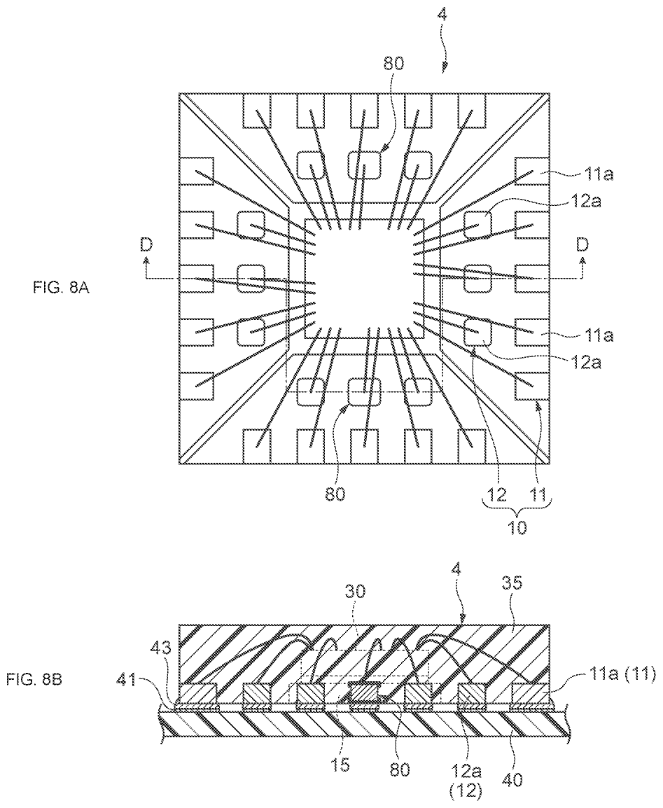

FIG. 8A is a plan view showing an electronic apparatus according to a fourth embodiment of the present technology. FIG. 8B is a cross-sectional view along D-D line of FIG. 8A and shows the electronic apparatus mounted on a mount board.

An electronic apparatus 4 according to the fourth embodiment has a passive component 80, of which structure is different from that of the electrode parts 63 of the passive component 60 of the second embodiment. FIG. 9E is a side view showing the passive component 80, and FIG. 9F is a cross-sectional view thereof. The passive component 80 includes electrode parts 83 provided on the both upper and lower ends of a body 81. The material composition of the electrode parts 83 is the same as that of, for example, the electrode parts 73 shown in FIG. 9D. In addition, the material composition of the electrode parts 83 may also be the same as that of the electrode parts 63 shown in FIG. 9B.

The area of the electrode part 83 of the passive component 80 to be connected is larger than each area of the electrode part 63 of the passive component 60 and the electrode part 73 of the passive component 70. Thus, wire bonding and mounting may be performed easily and certainly, and the reliability of connection may improve.

### 5. Fifth Embodiment

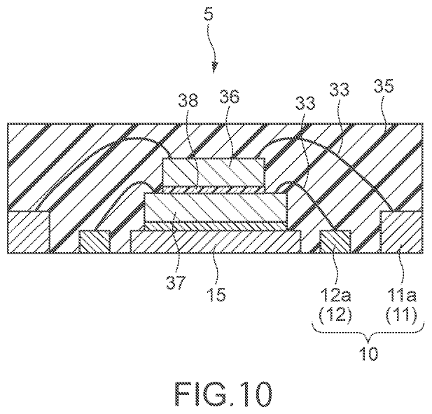

FIG. 10 is a cross-sectional view showing an electronic apparatus according to a fifth embodiment of the present technology. The electronic apparatus includes a second circuit chip 37, and a first circuit chip 36 mounted above the second circuit chip 37. An insulating layer 38 is provided between the first circuit chip 36 and the second circuit chip 37.

In addition, the electronic apparatus 5 includes the outer-circular-row connection terminal group 11 arranged in a first row and the inner-circular-row connection terminal group 12 arranged in a second row (inside the outer-circular-row connection terminal group 11). The height of the connection terminal 11a of the outer-circular-row connection terminal group 11 is higher than the height of the connection terminal 12a of the inner-circular-row connection terminal group 12.

The first circuit chip 36 is connected to the outer-circular-row connection terminal group 11 by the wires 33 respectively. The second circuit chip 37 is connected to the inner-circular-row connection terminal group 12 by the wires 33 respectively.

For example, the inner-circular-row connection terminal group 12 is mounted in another process (post process) as shown in FIG. 2B, and the electronic apparatus 5 is thereby manufactured. On the other hand, as described below, the die pad 15 and/or the outer-circular-row connection terminal group 11 may also be mounted in another process (post process) similarly.

Thus, the respective components of the electronic apparatus 5 are arranged in a dense state since the circuit chips 30 have a layered state and the connection terminal group 10 has a plurality of rows, and miniaturization of the electronic apparatus 5 may be realized.

Note that the height of the connection terminal 11a of the outer-circular-row connection terminal group 11 may be smaller than the height of the connection terminal 12a of the inner-circular-row connection terminal group 12.

### 6. Various Other Embodiments

The present technology is not limited to the embodiments described above, and various other embodiments may be realized.

As for each of the electronic apparatuses 1 to 5 according to the above respective embodiments, the example of the connection terminal group 10 (outer-circular-row connection terminal group 11 and inner-circular-row connection terminal group 12) mounted in two rows around the circuit chip 30 is shown. However, the connection terminal group 10 may be mounted in three or more rows around the circuit chip 30. In such a case, for example, the connection terminal groups other than the most-outer-circular-row connection terminal group of the connection terminal group 10 in three or more rows may be mounted on the tape member 28 in a process different from the process in which the tape member 28 is attached to the lead frame member 20.

In the above respective embodiments, the connection terminal is taken as the example of the lead frame part mounted in another process. However, in addition to the connection terminal, or in place of the connection terminal, the die pad 15 may be the lead frame part mounted in another process (post process). Due to this, the degree of freedom to which the die pad 15 is arranged may increase. When both of the die pad 15 and the inner-circular-row connection terminal group 12 are mounted in another process (post process), the die pad 15 arranged on a center position (first position) may be mounted earlier than the connection terminal 12a arranged around the center position (second position), and the order may be opposite.

Similarly, the connection terminal 11a of the outer-circular-row connection terminal group 11 may be the lead frame part mounted on the tape member 28 in another process (post process).

Similarly, both of the die pad 15 and electronic element components (for example, the passive components 60, 70, and 80) may be mounted on the first position and the second position of the tape member 28 respectively in another process (post process).

When the die pad 15 is the lead frame part mounted in another process, the hanging part 17 hanging the die pad 15 is not also needed.

As the above electronic element component, the passive components 60, 70, and 80 are taken as the example. However, a component having a function of an active component or another component may be used.

The technology is applied to a QFN packaged type apparatus. In addition, the technology may also be applied to a DFN (Dual flat non-leaded) packaged apparatus or another similar packaged apparatus.

Among the characteristic parts according to the respective embodiments described above, it is also possible to combine at least two of the characteristic parts together.

Note that the present technology may also employ the following configurations.
(1) A method of manufacturing a lead frame, including:
attaching a tape member to a lead frame member including at least a lead frame rim; and
mounting a lead frame part including at least one of a die pad or a connection terminal on the tape member in the lead frame rim.
(2) The method of manufacturing a lead frame according to claim 1, further including
forming the lead frame part by at least die-cutting a metal plate before the step of mounting the lead frame part on the tape member.

(3) The method of manufacturing a lead frame according to (2), in which
the step of forming the lead frame part includes forming a recess part on the metal plate by stamping, and
the die-cutting is performed after forming the recess part so that the lead frame part includes the recess part.
(4) The method of manufacturing a lead frame according to any one of (1) to (3), in which
the lead frame member includes
   the die pad, and
   a first connection terminal group provided around the die pad, and
the step of mounting the lead frame part on the tape member includes mounting a second connection terminal group on the tape member so that the second connection terminal group is arranged between the die pad and the first connection terminal group.
(5) The method of manufacturing a lead frame according to any one of (1) to (3), in which
the lead frame member includes a first connection terminal group provided around the die pad, and
the step of mounting the lead frame part on the tape member includes
   mounting the die pad on a first position of the tape member, and mounting a second connection terminal group on a second position of the tape member, the second position being around the first position and inside the first connection terminal group.
(6) A method of manufacturing an electronic apparatus, including:
attaching a tape member to a lead frame member including at least a lead frame rim;
mounting a lead frame part including a die pad and a connection terminal on the tape member in the lead frame rim;
mounting a circuit chip on the die pad;
connecting the circuit chip to the connection terminal by a wire; and
sealing the circuit chip and the wire with resin.
(7) The method of manufacturing an electronic apparatus according to (6), in which
the lead frame member includes
   the die pad, and
   a first connection terminal group provided around the die pad, and
the step of mounting the lead frame part on the tape member includes mounting a second connection terminal group on the tape member so that the second connection terminal group is arranged between the die pad and the first connection terminal group.
(8) The method of manufacturing an electronic apparatus according to (6), in which
the lead frame member includes a first connection terminal group provided around the die pad, and
the step of mounting the lead frame part on the tape member includes
   mounting the die pad on a first position of the tape member, and
   mounting a second connection terminal group on a second position of the tape member, the second position being around the first position and inside the first connection terminal group.
(9) The method of manufacturing an electronic apparatus according to (6), in which
the lead frame member includes
   the die pad, and
   a connection terminal group provided around the die pad, and
the method further includes mounting an electronic element component between the die pad and the connection terminal group.
(10) The method of manufacturing an electronic apparatus according to (6), in which
the lead frame member includes a connection terminal group provided around the die pad, and
the method further includes:
mounting the die pad on a first position of the tape member; and
mounting an electronic element component on a second position of the tape member, the second position being around the first position and inside the first connection terminal group.
(11) An electronic apparatus, including:
a die pad including a bottom surface;
connection terminal groups respectively including bottom surfaces, the bottom surfaces being arranged on a plane same as a reference plane, the reference plane including the bottom surface of the die pad, the connection terminal groups being arranged in a plurality of rows around the die pad;
a circuit chip provided on the die pad;
wires respectively connecting the circuit chip to a plurality of predetermined connection terminals of the connection terminal; and
resin including a bottom surface arranged on the reference plane and sealing the circuit chip and the wires.
(12) The method of manufacturing the electronic apparatus according to (11), in which
the plurality of circuit chips are provided in a layered state, and
a first circuit chip of the plurality of circuit chips and a connection terminal group in a first row of the connection terminal groups are connected respectively by the wires, and
a second circuit chip of the plurality of circuit chips and a connection terminal group in a second row of the connection terminal groups are connected respectively by the wires, height of the connection terminal group in the second row being different from height of the connection terminals in the first row.

### REFERENCE SIGNS LIST

1, 2, 3, 4, 5 electronic apparatus
10 connection terminal group
11 outer-circular-row connection terminal group
11a, 12a connection terminal
12 inner-circular-row connection terminal group
15 die pad
15b bottom surface
20 lead frame member
20A lead frame
21 lead frame rim
25 metal plate
26 recess part
28 tape member
30 circuit chip
33 wire
35 sealing resin
35b bottom surface
36 first circuit chip
37 second circuit chip
40 mount board
60, 70, 80 passive component
63, 73, 83 electrode part

1. A method of manufacturing a lead frame, comprising:
attaching a tape member to a lead frame member including at least a lead frame rim; and
mounting a lead frame part including at least one of a die pad or a connection terminal on the tape member in the lead frame rim.

2. The method of manufacturing a lead frame according to claim 1, further comprising
forming the lead frame part by at least die-cutting a metal plate before the step of mounting the lead frame part on the tape member.

3. The method of manufacturing a lead frame according to claim 2, wherein
the step of forming the lead frame part includes forming a recess part on the metal plate by stamping, and
the die-cutting is performed after forming the recess part so that the lead frame part includes the recess part.

4. The method of manufacturing a lead frame according to claim 1, wherein
the lead frame member includes
the die pad, and
a first connection terminal group provided around the die pad, and
the step of mounting the lead frame part on the tape member includes mounting a second connection terminal group on the tape member so that the second connection terminal group is arranged between the die pad and the first connection terminal group.

5. The method of manufacturing a lead frame according to claim 1, wherein
the lead frame member includes a first connection terminal group provided around the die pad, and
the step of mounting the lead frame part on the tape member includes
mounting the die pad on a first position of the tape member, and
mounting a second connection terminal group on a second position of the tape member, the second position being around the first position and inside the first connection terminal group.

6. A method of manufacturing an electronic apparatus, comprising:
attaching a tape member to a lead frame member including at least a lead frame rim;
mounting a lead frame part including a die pad and a connection terminal on the tape member in the lead frame rim;
mounting a circuit chip on the die pad;
connecting the circuit chip to the connection terminal by a wire; and
sealing the circuit chip and the wire with resin.

7. The method of manufacturing an electronic apparatus according to claim 6, wherein
the lead frame member includes
the die pad, and
a first connection terminal group provided around the die pad, and
the step of mounting the lead frame part on the tape member includes mounting a second connection terminal group on the tape member so that the second connection terminal group is arranged between the die pad and the first connection terminal group.

8. The method of manufacturing an electronic apparatus according to claim 6, wherein
the lead frame member includes a first connection terminal group provided around the die pad, and
the step of mounting the lead frame part on the tape member includes
mounting the die pad on a first position of the tape member, and
mounting a second connection terminal group on a second position of the tape member, the second position being around the first position and inside the first connection terminal group.

9. The method of manufacturing an electronic apparatus according to claim 6, wherein
the lead frame member includes
the die pad, and
a connection terminal group provided around the die pad, and
the method further comprises mounting an electronic element component between the die pad and the connection terminal group.

10. The method of manufacturing an electronic apparatus according to claim 6, wherein
the lead frame member includes a connection terminal group provided around the die pad, and
the method further comprises:
mounting the die pad on a first position of the tape member; and
mounting an electronic element component on a second position of the tape member, the second position being around the first position and inside the first connection terminal group.

11. An electronic apparatus, comprising:
a die pad including a bottom surface;
connection terminal groups respectively including bottom surfaces, the bottom surfaces being arranged on a plane same as a reference plane, the reference plane including the bottom surface of the die pad, the connection terminal groups being arranged in a plurality of rows around the die pad;
a circuit chip provided on the die pad;
wires respectively connecting the circuit chip to a plurality of predetermined connection terminals of the connection terminal groups; and
resin including a bottom surface arranged on the reference plane and sealing the circuit chip and the wires.

12. The method of manufacturing the electronic apparatus according to claim 11, wherein
the plurality of circuit chips are provided in a layered state, and
a first circuit chip of the plurality of circuit chips and a connection terminal group in a first row of the connection terminal groups are connected respectively by the wires, and
a second circuit chip of the plurality of circuit chips and a connection terminal group in a second row of the connection terminal groups are connected respectively by the wires, height of the connection terminal group in the second row being different from height of the connection terminals in the first row.
